(19) United States
(12) Patent Application Publication
(10) Pub. No.: US 2017/0077154 A1
(43) Pub. Date: Mar. 16, 2017

(54) IMAGE SENSOR AND IMAGE PICKUP APPARATUS INCLUDING THE SAME

(71) Applicant: CANON KABUSHIKI KAISHA, Tokyo (JP)

(72) Inventor: Aihiko Numata, Inagi-shi (JP)

(21) Appl. No.: 15/256,289

(22) Filed: Sep. 2, 2016

(30) Foreign Application Priority Data
Sep. 10, 2015 (JP) 2015-178951

(51) Int. Cl. H01L 27/146

(52) U.S. Cl. CPC H01L 27/14607; H01L 27/14643; H01L 27/14627

(57) ABSTRACT

An image sensor includes a plurality of pixels. Each of the plurality of pixels includes a microlens, a waveguide unit having a core and a cladding and capable of propagating light transmitted through the microlens, and a pair of photo diodes and configured to carry out photoelectric conversion of light guided by the waveguide unit. Each of the pixels includes an absorption unit that is electrically independent, and the absorption unit has an optical absorptance with respect to a light beam to be photoelectrically converted by the pair of photo diodes higher than an optical absorptance of the core and of the cladding. An optical distance between the absorption unit and an interface of the cladding and the core on the side toward the microlens is no greater than a wavelength of the light beam to be converted.

### BACKGROUND OF THE INVENTION

Field of the Invention

The present invention relates to an image sensor for use in an image pickup apparatus, such as a digital still camera or a digital video camera, and relates to an image pickup apparatus including the image sensor.

Description of the Related Art

An autofocus (AF) technique in a digital still camera, a digital video camera, or the like is known. With regard to the AF technique, Japanese Patent Application Laid-Open No. 2009-158800 proposes an image sensor having a plurality of pixels, and at least some of the pixels are provided with a pair of photo diodes. This is sometimes referred to as a “dual pixel” AF sensor. With the use of an output signal from this image sensor, AF through a phase difference system can be achieved.

The phase difference system is an AF system that uses a pair of output signals from a pair of photo diodes which detect a pair of incident light beams that have passed through different regions of a pupil of an imaging optical system (hereinafter, simply referred to as a pair of incident light beams). A pair of images (two images) are acquired with the use of the stated pair of output signals, and the out-of-focus amount is determined by detecting the offset amount between the acquired two images (hereinafter, referred to as an image offset amount). Unlike the so-called contrast AF system, the phase difference AF system eliminates the need for the so-called hunting or wobbling of moving a lens back and forth during the focusing operation. Accordingly, high-speed and high-precision AF can theoretically be achieved.

Japanese Patent Application Laid-Open No. 2009-158800 discloses a pixel structure in which a pixel includes a microlens, a waveguide unit, and a pair of photo diodes. With this pixel structure, each of a pair of incident light beams is selectively guided to a corresponding one of a pair of photo diodes. Thus, AF can be achieved through the phase difference system with the use of a pair of output signals from a pair of photo diodes.

When the ratio of the focal length to the diameter (F-number) of a lens (imaging optical system) used in an image pickup apparatus is small, the proportion of the light beam, of a pair of incident light beams, that is incident on a pixel at a large angle of incidence (hereinafter, simply referred to as a light beam having a large angle of incidence) increases, as compared to a case in which the F-number of such a lens is large and the angle of incidence is small. The light beam having a large angle of incidence is refracted a number of times at an interface between a core and a cladding of a waveguide unit and is likely to be guided to an unintended photo diode (to which the light beam is not supposed to be guided) of a pair of photo diodes.

As a result, the AF technique described in Japanese Patent Laid-Open No. 2009-158800 lacks AF accuracy in a case where the F-number of a lens used in the image pickup apparatus is small, as compared to a case in which the F-number is large.

### SUMMARY OF THE INVENTION

The various embodiments of the present invention describe an image sensor configured to prevent a light beam having a large angle of incidence from being guided to an unintended photo diode of a pair of photo diodes.

According to an aspect of the present invention, an image sensor includes a plurality of pixels arrayed in a two-dimensional plane containing a first direction and a second direction perpendicular to the first direction. Each of the plurality of pixels includes, arranged in a third direction perpendicular to the plane, a microlens, a waveguide unit having a core and a cladding and capable of propagating light transmitted through the microlens, and a pair of photo diodes arrayed in the first direction and configured to carry out photoelectric conversion of light guided by the waveguide unit. Each of the pixels includes an absorption unit that is electrically independent, and the absorption unit has an optical absorptance with respect to a light beam to be photoelectrically converted by the pair of photo diodes higher than an optical absorptance of the core and of the cladding. The absorption unit is provided in the first direction of the core as viewed in the third direction. An optical distance between the absorption unit and an interface of the cladding on the side toward the microlens in the third direction is no greater than a wavelength of the light beam.

Further features and advantages of the present invention will become apparent from the following description of exemplary embodiments with reference to the attached drawings.

### BRIEF DESCRIPTION OF THE DRAWINGS

FIG. 1 is a schematic sectional view (XZ plane) of an image pickup apparatus provided with an image sensor according to exemplary embodiments (first and second exemplary embodiments) of the present invention.

FIG. 2 is a sectional view (XZ plane) of a pixel according to one mode of the first exemplary embodiment.

FIG. 3 is a schematic sectional view (XZ plane) of a core and a cladding according to one mode of the first exemplary embodiment.

FIG. 4A is a sectional view (XZ plane) of a pixel according to one mode of the first exemplary embodiment.

FIG. 4B is a sectional view (XZ plane) of a pixel according to one mode of the first exemplary embodiment.

FIG. 4C is a sectional view (XZ plane) of a pixel according to one mode of the first exemplary embodiment.

FIG. 4D is a sectional view (XZ plane) of a pixel according to one mode of the first exemplary embodiment.

FIG. 5 is a graph illustrating a relationship between the quantity of light incident on a pair of photo diodes and the angle of incidence according to one mode of the first exemplary embodiment.

FIG. 6 is a graph illustrating a relationship between the quantity of light incident on a photo diode and the angle of incidence according to one mode of the first exemplary embodiment.

FIG. 7A is a sectional view (XZ plane) of a pixel according to another mode of the first exemplary embodiment.

FIG. 7B is a sectional view (XZ plane) of a pixel according to another mode of the first exemplary embodiment.

FIG. 7C is a sectional view (XY plane) of pixels according to another mode of the first exemplary embodiment.

FIG. 7D is a sectional view (XY plane) of pixels according to another mode of the first exemplary embodiment.

FIG. 8 is a sectional view (XZ plane) of a pixel according to another mode of the first exemplary embodiment (schematically illustrating a state in which a light beam is propagated).

FIG. 9 is a plan view (XY plane) of an image sensor according to the second exemplary embodiment.

FIGS. 10A and 10B are each a sectional view (XZ plane) of a pixel according to the second exemplary embodiment.

### DESCRIPTION OF THE EMBODIMENTS

Hereinafter, an image sensor according to exemplary embodiments of the present invention will be described with reference to the drawings. In all of the drawings, components having identical functions are given identical reference characters.

### First Exemplary Embodiment

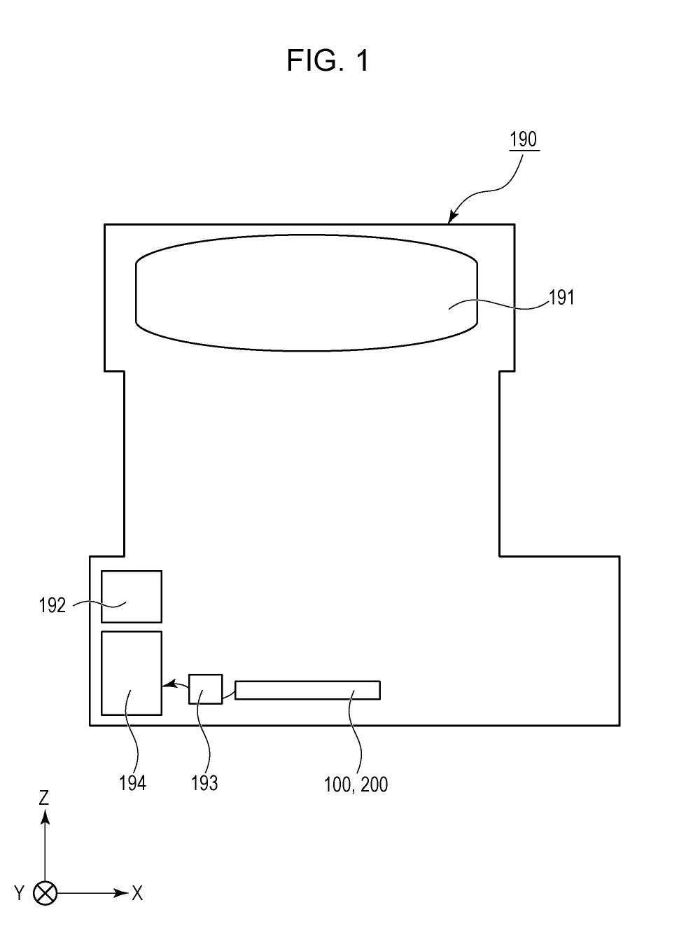

FIG. 1 is a schematic sectional view (XZ plane) of an image pickup apparatus 190, such as a digital still camera or a digital video camera, provided with an image sensor according to an exemplary embodiment of the present invention.

The image pickup apparatus 190 includes an imaging optical system 191, an image sensor 100 (200) configured to receive light from the imaging optical system 191, a central processing unit (CPU) 192, a transfer circuit 193, and a signal processing unit 194.

The CPU 192 controls the operations of the transfer circuit 193 and the signal processing unit 194.

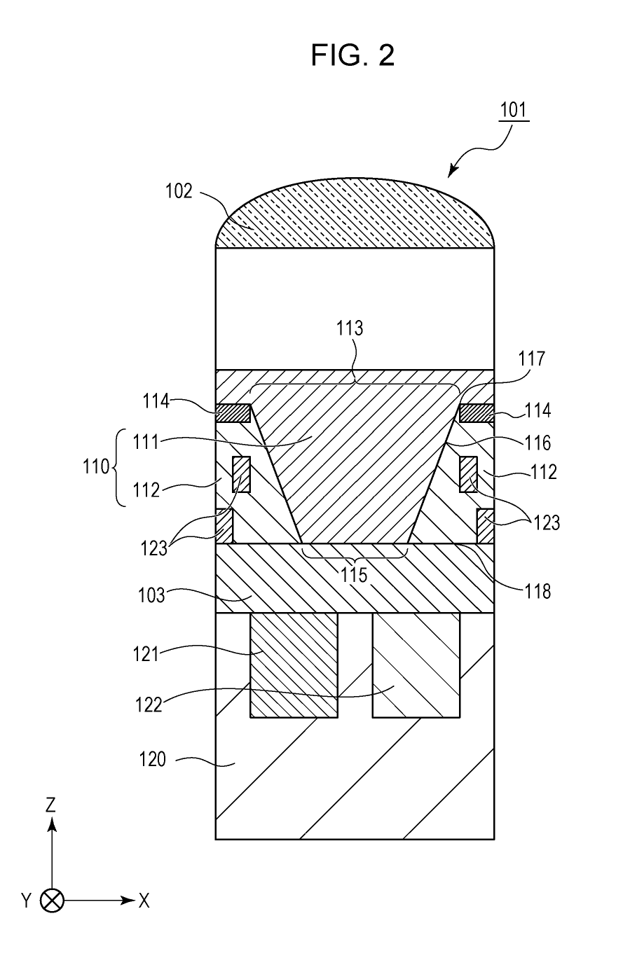

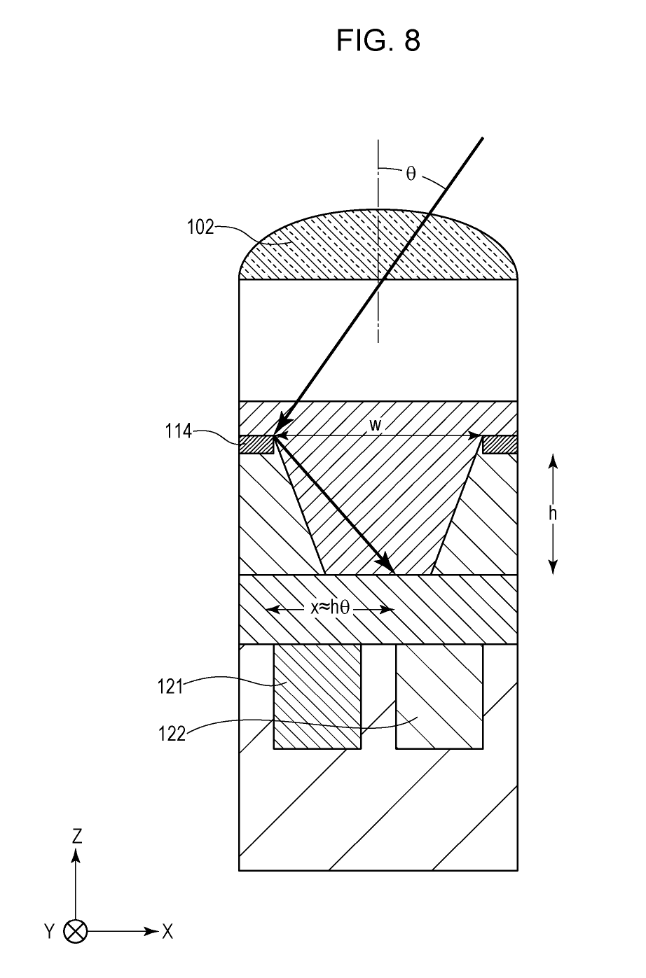

AF can be achieved through a phase difference system by detecting an image offset amount acquired with the use of output signals from respective photo diodes 121 and 122 (see FIGS. 2, 8). A signal for a captured image can also be acquired by adding output signals from the respective photo diodes 121 and 122.

FIG. 2 is a sectional view (XZ plane) of one of a plurality of pixels provided in the image sensor 100 (see FIG. 1) according to a first exemplary embodiment. The image sensor 100 includes a plurality of pixels arrayed in a plane (XY plane) containing a first direction (±X-axis direction) and a second direction (±Y-axis direction) that is perpendicular to the first direction. The first direction and the second direction will be described later.

Each of a plurality of pixels 101 includes, from a side on which a light beam is incident, a microlens 102, a waveguide unit 110, a gettering layer 103, and a pair of photo diodes formed by a first photo diode 121 and a second photo diode 122. The gettering layer 103 is a layer having an anti-reflection function or a gettering function. Gettering is a process of forming porous silicon layers or dielectric material (for example, BPSG) layers on one or both sides of silicon wafers whereby metal contamination is rendered harmless to the operation of the substrate. A gettering layer can enhance the electronic properties (in particular, trapping metal ion impurities in gettering layers) of a semiconductor layer. As the pixel 101 includes the pair of photo diodes 121 and 122, the pixel 101 can be used not only for capturing an image but also for the phase difference AF or for measuring the distance or information corresponding the distance (ranging) of a scene or object being imaged.

The microlens 102 is a fine lens formed through a micromachining technique and has an aperture of several micrometers to several hundred micrometers.

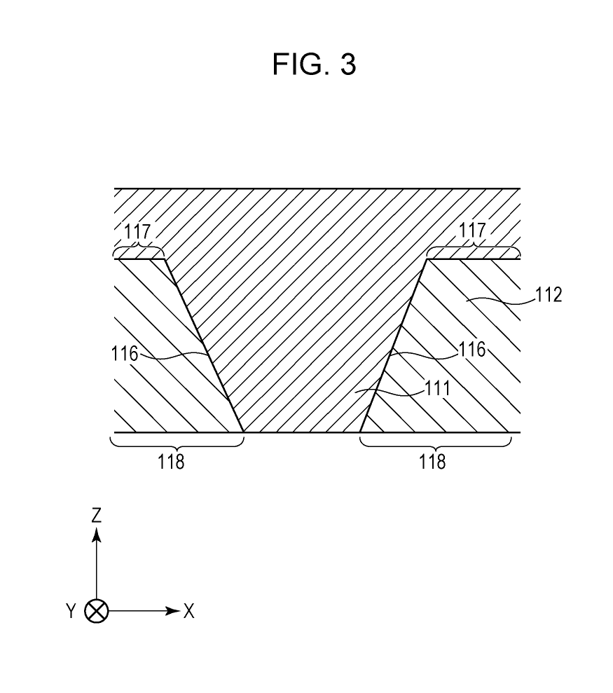

The waveguide unit 110 includes a core 111 and a cladding 112 (the cladding 112 having a refractive index smaller than the refractive index of the core 111). The waveguide unit 110 has a waveguide structure capable of propagating light transmitted through the microlens 102 to each of the photodiodes 121 and 122. The waveguide unit 110 includes an incident end 113 (distal end) and an exit end 115 (proximal end). The incident end 113 is an end of the core 111 on the side where light transmitted through the microlens 102 is incident on the core 111. The diameter of the incident end 113 of the waveguide unit coincides with the inner diameter of an interface (second interface) 117 of the cladding 112 on the side closest toward the microlens 102 (see FIGS. 2 and 3). The exit end 115 is another end of the core 111 through which light that has entered the waveguide unit 110 is emitted. The diameter of the exit end 115 coincides with the inner diameter of an interface (third interface) 118 of the cladding 112 on the side closest toward the pair of photo diodes (see FIGS. 2 and 3).

The pair of photo diodes 121 and 122 carry out photoelectric conversion of light beams guided by the waveguide unit 110 (exit end 115). The pair of photo diodes 121 and 122 are provided in a substrate 120. In addition, the pair of photo diodes 121 and 122 are arrayed (disposed) side by side in the YX plane. The direction in which the pair of photo diodes 121 and 122 are arrayed side by side is referred to as the first direction, hereinafter. The first direction coincides with the ±X-axis direction indicated in FIG. 2 and so on.

The substrate 120 is formed of a material such as silicon. The material for the substrate 120 is selected as appropriate in accordance with the wavelength band to be detected by the pair of photo diodes 121 and 122. The pair of photo diodes 121 and 122 have a potential gradient, and this potential gradient is determined through a process of ion implantation or the like into the substrate 120.

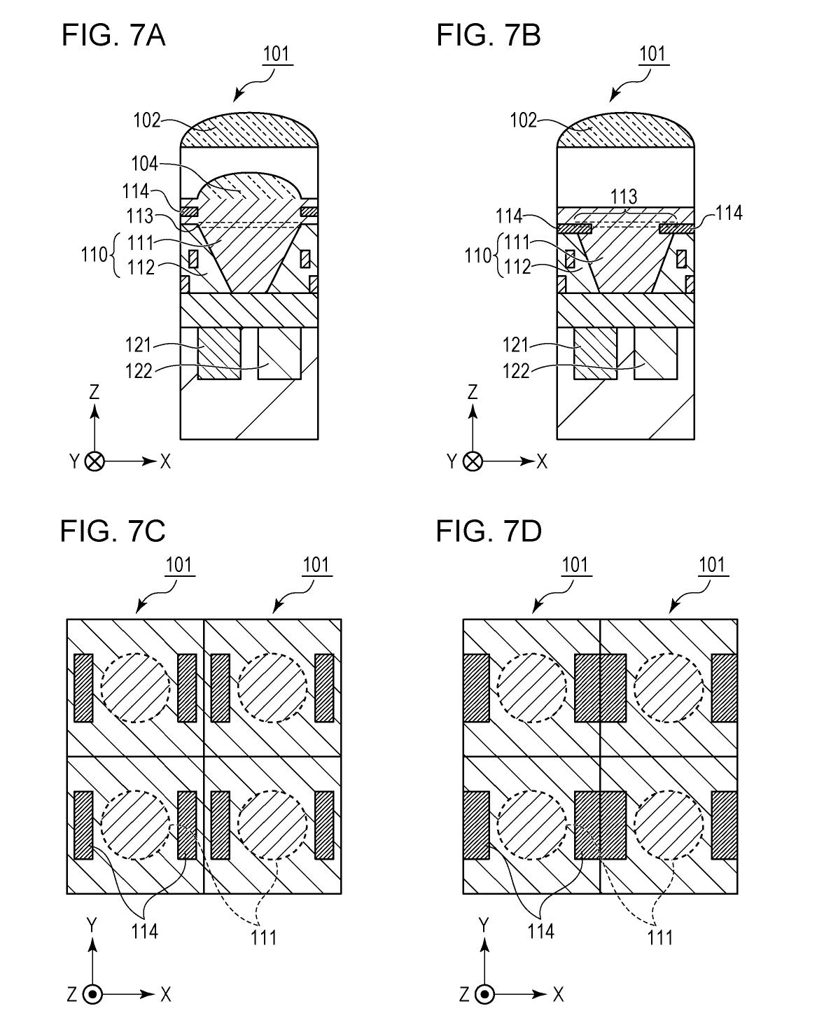

The plurality of pixels 101 are arrayed in a row in the first direction (see FIGS. 7C and 7D). The plurality of pixels 101 are also arrayed in a row in a direction perpendicular to the first direction. The direction in which the plurality of pixels 101 are arrayed and that is perpendicular to the first direction is referred to as the second direction, hereinafter. The second direction coincides with the ±Y-axis direction indicated in FIG. 2 and so on. Accordingly, the first and second directions are directions defined in the YX plane of FIG. 2.

The microlens 102, the waveguide unit 110, and the gettering layer 103 are provided in a direction perpendicular to a plane (XY plane) that contains the first direction and the second direction. The direction that is perpendicular to the plane containing the first direction and the second direction is referred to as a third direction, hereinafter. The third direction coincides with the ±Z-axis direction indicated in FIG. 2, and the third direction is the direction in which light propagates through the optical system 191.

The microlens 102 and the waveguide unit 110 have a function of selectively guiding each light beam of a pair of incident light beams to a corresponding one of the photo diodes 121 and 122. In that regard, the microlens 102 and the waveguide unit 110 are considered to have a pupil splitting function. The direction in which the pupil is split in this function is referred to as a pupil splitting direction. By detecting an image offset amount acquired with the use of output signals from the respective photo diodes 121 and 122, AF can be achieved through a phase difference technique. In addition, the ranging can also be achieved.

The microlens 102, the core 111, the cladding 112, and the gettering layer 103 are formed of a material such as silicon oxide, silicon nitride, borophosphosilicate glass (BPSG), or an organic material. It is to be noted that the cladding 112 needs to be provided (formed) by a material having a refractive index that is lower than the refractive index of the core 111 (the refractive index of the core 111 is higher than the refractive index of the cladding 112).

The image sensor 100 includes wires 123. The wires 123 are provided toward the cladding 112 relative to an interface (first interface) 116 of the cladding 112 and the core 111, as illustrated in FIGS. 2 and 3. In other words, the wires 123 are provided in the cladding 112. Imaging signals acquired by the pair of photo diodes 121 and 122 are transmitted to the wires 123. The wires 123 are formed, for example, by a metal material, such as Al or Cu. The imaging signals are transmitted through the wires 123 from the pair of photo diodes 121 and 122 to scanning circuits (peripheral circuits not illustrated) provided in the image sensor 100.

The image sensor 100 includes absorption units 114. The absorption units 114 are provided in the first direction relative to the core 111. The absorption units 114 have an optical absorptance with respect to the incident light beam to be converted (light beams to be photoelectrically converted) by the pair of photo diodes 121 and 122. The optical absorptance (hereinafter, simply referred to as the optical absorptance) of the absorption units 114 is higher than the optical absorptances of both the core 111 and the cladding 112. Therefore, the absorption units 114 are formed of a material having an optical absorptance higher than the optical absorptances of the materials forming the core 111 and the cladding 112, and examples of such materials include a metal material, such as Al or Cu, and an organic material, such as a colorant. The absorption units 114 may be formed by a material having an extinction coefficient (attenuation) of at least 0.01 with respect to the light to be photoelectrically converted. In addition, the absorption units 114 may be formed by a material that is the same as the material for the wires 123 or may be formed by a material that is different from the material for the wires 123, as long as the absorptance requirements are met. Preferably, the optical absorptance of the absorption units 114 is no less than 0.1, and more preferably the optical absorptance is no less than 1.0. Here, it should be noted that “absorptance” of the surface of a material is its effectiveness in absorbing radiant energy. It is the fraction of incident electromagnetic power that is absorbed at an interface of the surface of a material with a surrounding medium, in contrast to the absorption coefficient, which is the ratio of the absorbed to incident electric field.

The absorption unit 114 is electrically independent from the wires 123. The expression “electrically independent” means that the series resistance between the wires 123 and the absorption units 114 through which imaging signals are transmitted is no less than 1 megohm, for example. The wires 123 do not function as the absorption units, and the absorption units 114 are electrically independent (the absorption units 114 are provided independently from the wires 123). Thus, deterioration in the transmission characteristics can be suppressed. Deterioration in the transmission characteristics can occur as light is absorbed by the wires, but the absorption units 114 are not used as the wires, and thus the aforementioned deterioration of transmission does not occur.

It is preferable that the absorption units 114 and the wires 123 be provided at positions offset from each other within the XY plane. With this configuration, capacitive coupling between the absorption units 114 and the wires 123 can be reduced. Furthermore, it is preferable that the absorption units 114 be provided on the side of the wires 123 that is toward the microlens 102. With this configuration, the absorption units are closer to a light source than the wires, and a larger quantity of light is absorbed by the absorption units. Thus, light is not absorbed by the wires and deterioration in the transmission characteristics of the wires 123 can be suppressed.

In the image sensor 100 according to an exemplary embodiment of the present invention, the pixel 101 includes the absorption units 114, and thus a light beam having a large angle of incidence is prevented from being guided to an unintended photo diode of the pair of photo diodes even in a case in which the F-number of the imaging optical system is small. Thus, the AF accuracy and the ranging accuracy is significantly improved. This will be described hereinafter. In the following description, the angle of incidence relative to a pixel is defined not as an angle of incidence relative to the microlens 102 but as an angle of incidence relative to an axis extending in the third direction. In addition, the angle of incidence relative to the pixel is also referred to simply as the angle of incidence.

First, the principle of splitting the pupil by the microlens 102 and the waveguide unit 110 will be described.

Light beams that have passed through different regions of the exit pupil of the imaging optical system are incident on a pixel as light beams having different angles of incidence. Therefore, by selectively guiding the light beams incident at different angles of incidence to the respective photo diodes, the pupil can be effectively split.

When a light beam is incident on the microlens 102, the light beam is condensed at a different position on the incident end 113 depending on the angle of incidence of the light beam. The light beam is then converted to a waveguide mode corresponding to the position at which the light beam has been condensed and propagates through the waveguide unit. Therefore, by appropriately designing the shape of the microlens 102, the shape and the medium of the waveguide unit 110, and the positions of the pair of photo diodes 121 and 122, the waveguide mode to which a light beam is converted can be controlled. As a result, light beams can be selectively guided to the respective photo diodes in accordance with the angles of incidence of the light beams, and it becomes possible to split the pupil and accurately guide the incident light beams to the photodiodes.

In the pixel illustrated in FIG. 2, the first direction (±X-axis direction) corresponds to the pupil splitting direction. A light beam incident obliquely in the −X-axis direction and the −Z-axis direction is selectively guided to the photo diode 121, and a light beam incident obliquely in the +X-axis direction and the −Z-axis direction is selectively guided to the photo diode 122.

Next, an effect of the absorption units 114 on a light beam incident on the pixel 101 will be described with reference to the drawings.

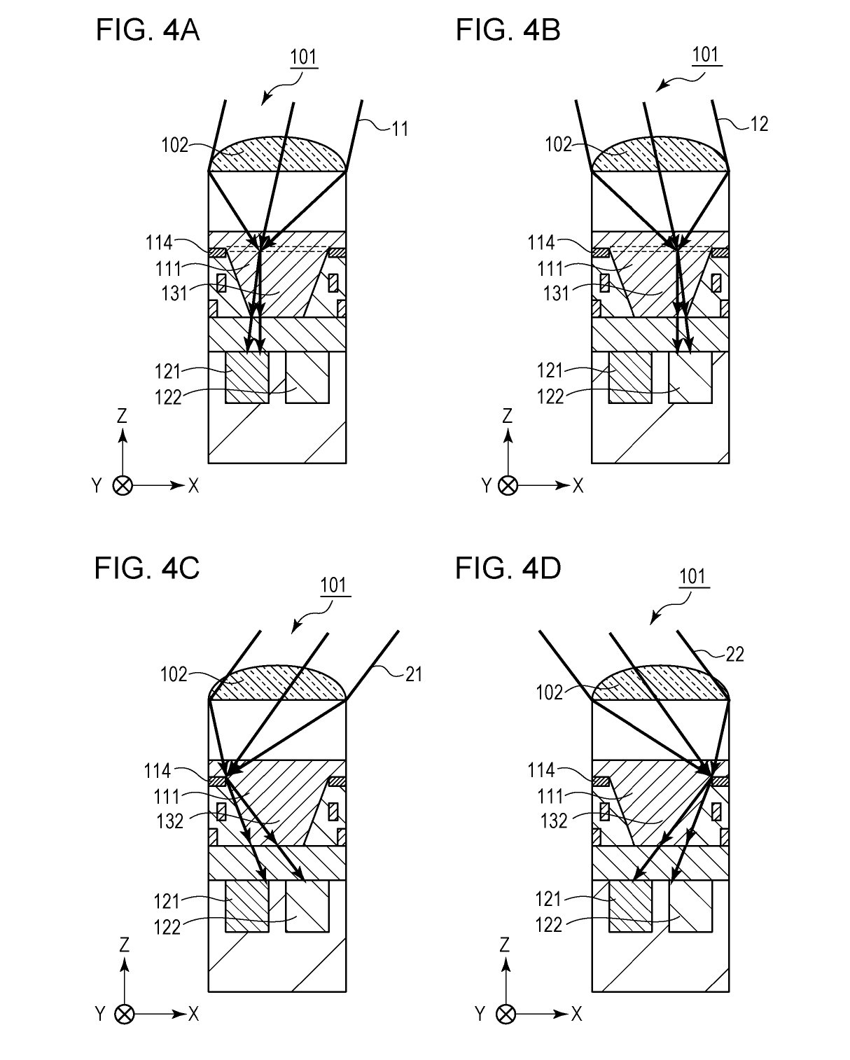

FIGS. 4A through 4D schematically illustrate a state in which light beams incident on the pixel 101 at different angles of incidence relative to the third direction propagate through the pixel 101. FIGS. 4A and 4B schematically illustrate a state in which light beams incident on the pixel 101 at relatively small angles of incidence (light beams 11 and 12 having small angles of incidence) propagate through the pixel 101. FIGS. 4C and 4D schematically illustrate a state in which light beams incident on the pixel 101 at relatively large angles of incidence (light beams 21 and 22 having large angles of incidence) propagate through the pixel 101.

The light beams 11 and 12 having small angles of incidence are condensed by the microlens 102 near the center of the incident end 113 in the first direction. Typically, a light beam incident closer to the center of the incident end 113 in the first direction couples to a lower-order waveguide mode 131. The light beam that has coupled to the lower-order waveguide mode 131 propagates through the waveguide unit 110 at a relatively small angle relative to the third direction. Therefore, the light beams 11 and 12 having small angles of incidence are selectively incident on either one (desired photo diode) of the pair of photo diodes 121 and 122.

On the other hand, the light beams 21 and 22 having large angles of incidence are condensed by the microlens 102 near an edge portion of the incident end 113 in the first direction. Typically, a light beam incident closer to the edge portion of the incident end 113 in the first direction couples to a higher-order waveguide mode 132. The light beam that has coupled to the higher-order waveguide mode 132 is diffracted by the first interface 116 and propagates through the waveguide unit 110 at a relatively large angle relative to the third direction. Therefore, the proportion of light that is incident on an undesired photo diode of the pair of photo diodes 121 and 122 is higher for the light beams 21 and 22 having large angles of incidence than for the light beams 11 and 12.

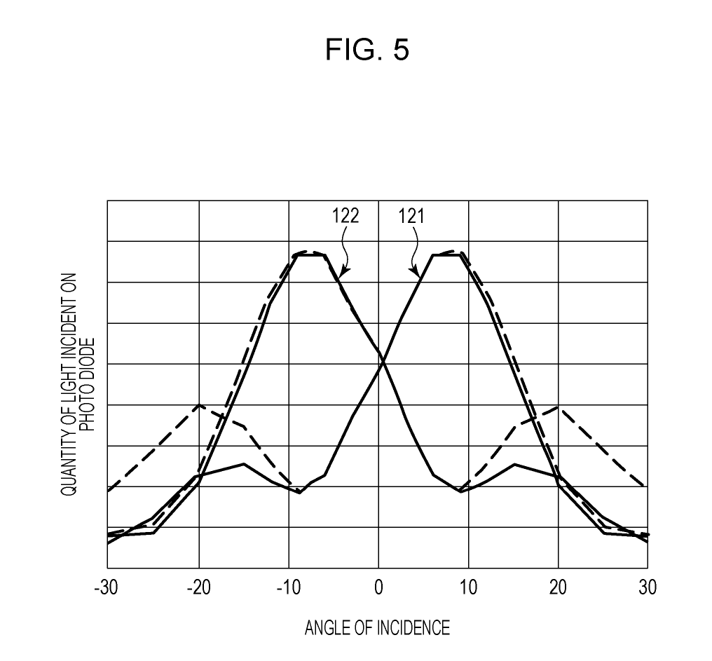

FIG. 5 illustrates a relationship between the quantity of light incident on the pair of photo diodes 121 and 122 and the angle of incidence (incident angular dependence of the quantity of incident light). The vertical axis represents the quantity of light incident on the photo diodes, and the horizontal axis represents the angle of incidence. With respect to the angle of incidence (horizontal axis), the angle of incidence of a light beam incident on the pixel 101 in the third direction (−Z-axis direction) is considered to be zero. In addition, the angle of incidence of a light beam incident obliquely in the −X-axis direction and the −Z-axis direction is positive, and the angle of incidence of a light beam incident obliquely in the +X-axis direction and the −Z-axis direction is negative.

The solid lines represent the incident angular dependence of the quantity of incident light when the absorption units 114 are provided in the pixel 101. Meanwhile, the dashed lines represent the incident angular dependence of the quantity of incident light when no absorption unit 114 is provided in the pixel 101.

The following tendencies are observed in a case in which the absorption units 114 are provided. Of the light beam incident at an angle of incidence of around +20 degrees relative to the third direction (±Z-axis direction), the component incident on the photo diode 122 deceases. In addition, of the light beam incident at an angle of incidence of around −20 degrees relative to the third direction, the component incident on the photo diode 121 deceases. Meanwhile, with respect to the light beams incident at angles of incidence of no greater than ±10 degrees relative to the third direction, the influence of the absorption units 114 is hardly observed. In other words, a light beam incident obliquely in the −X-axis direction and the −Z-axis direction can be selectively guided to the photo diode 121, and a light beam incident obliquely in the +X-axis direction and the −Z-axis direction can be selectively guided to the photo diode 122.

It is considered that, in a case in which the absorption units 114 are provided, the light beams condensed near the edge portions of the incident end 113 in the first direction are selectively absorbed by the absorption units 114 and the light beams 21 and 22 having large angles of incidence are absorbed before coupling to the higher-order waveguide mode 132 as a result. In other words, it is considered that, even in a case in which the light beams 21 and 22 having large angles of incidence are incident, a light beam incident obliquely in the −X-axis direction and the −Z-axis direction can be selectively guided to the photo diode 121 and a light beam incident obliquely in the +X-axis direction and the −Z-axis direction can be selectively guided to the photo diode 122.

FIGS. 2 and 4A through 4D illustrate a case in which the optical distance between the absorption units 114 and the interface (second interface) 117 of the cladding 112 on the side toward the microlens 102 in the third direction is zero. However, the distance between the absorption units 114 and the second interface 117 does not have to be zero. In other words, the absorption units 114 may be provided closer to the substrate than the second interface 117, or the absorption units 114 may be provided closer to the microlens 102 than the second interface 117. However, it is preferable that the optical distance between the absorption units 114 and the second interface 117 in the third direction be shorter. The reason therefor will be described hereinafter.

Typically, although the manner in which light spreads inside the waveguide unit differs in accordance with the order of the waveguide mode, the waveguide modes are distributed throughout the core of the waveguide unit. Therefore, light beams condensed at different positions on the incident end 113 spread throughout the core 111 of the waveguide unit 110 as the light beams propagate through the waveguide unit 110. In other words, light beams incident at different angles of incidence are separated in different X coordinates at a position closer to the incident end 113. Accordingly, as the optical distance between the absorption units 114 and the second interface 117 in the third direction is shorter, a light beam incident on the pixel 101 at a large angle of incidence is selectively absorbed by the absorption units 114, and the pupil splitting performance improves.

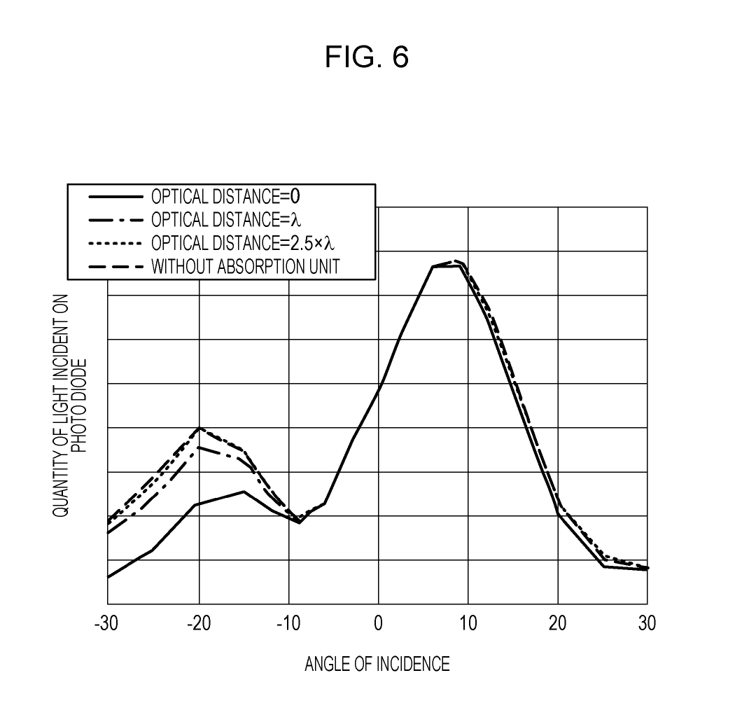

FIG. 6 illustrates a relationship between the quantity of light incident on the photo diode 121 and the angle of incidence (incident angular dependence of the quantity of incident light) when the Z-coordinate of (an interface of) the absorption unit 114 (on side on which a light beam is incident) (the optical distance between the absorption unit 114 and the second interface 117 in the third direction) is varied. The vertical axis represents the quantity of light incident on the photo diode, and the horizontal axis represents the angle of incidence. With respect to the angle of incidence (horizontal axis), the angle of incidence of a light beam incident on the pixel 101 in the third direction (−Z-axis direction) is considered to be zero. In addition, the angle of incidence of a light beam incident obliquely in the −X-axis direction and the −Z-axis direction is positive, and the angle of incidence of a light beam incident obliquely in the +X-axis direction and the −Z-axis direction is negative.

The solid line represents the incident angular dependence of the quantity of light incident on the photo diode in a case in which the interface of the absorption unit 114 on the side on which the light beam is incident coincides with the second interface 117 (in a case in which the optical distance between the absorption unit 114 and the second interface 117 in the third direction is zero). The interface of the absorption unit 114 on the side on which the light beam is incident is, among the interfaces of the absorption unit 114, an interface having the largest Z-coordinate value. The incident angular dependence of the quantity of light incident on the photo diode is also referred to simply as the incident angular dependence.

The dash-dotted line represents the incident angular dependence in a case in which the optical distance between the interface of the absorption unit 114 on the side on which the light beam is incident and the second interface 117 in the third direction is equal to the wavelength λ of the light beam to be photoelectrically converted. The dotted line represents the incident angular dependence in a case in which the optical distance between the interface of the absorption unit 114 on the side on which the light beam is incident and the second interface 117 in the third direction is 2.5 times the wavelength λ of the light beam to be converted. In addition, the dashed line represents the incident angular dependence in a case in which no absorption unit 114 is provided in the pixel 101.

The optical distance (optical distance) is a value obtained by multiplying the actual distance by the refractive index of the medium. It is to be noted that the incident angular dependence of the quantity of light incident on the photo diode 122 (not illustrated) is obtained by flipping, about 0 degrees, the positive side and the negative side of the incident angular dependence of the quantity of light incident on the photo diode 121 illustrated in FIG. 6.

FIG. 6 reveals that, as the optical distance between the absorption units 114 and the second interface 117 in the third direction (Z-axis direction) is shorter, of the light beam incident at an angle of incidence of around ±20 degrees, the component that could be incident on the opposite photo diode is selectively absorbed. In addition, FIG. 6 also reveals that, in a case in which the optical distance between the absorption units 114 and the second interface 117 in the third direction is longer than the wavelength λ of the light beam to be converted, the incident angular dependence is substantially the same as the incident angular dependence obtained when no absorption unit 114 is provided.

Accordingly, it is preferable that the optical distance between the absorption units 114 and the second interface 117 in the third direction be no greater than the wavelength λ of the light beam to be converted.

Furthermore, it is preferable that the optical distance between the absorption unit 114 and the first interface 116 in the first direction (X-axis direction) be no greater than the wavelength of the light beam to be converted. The reason therefor will be described hereinafter.

A light beam that has coupled to a waveguide mode propagates through the waveguide with a spread of approximately the length of the wavelength in the equivalent of the optical distance. In other words, the waveguide mode propagates not only inside the core 111 but also to a region inside the cladding 112 apart from the first interface 116 by the length of the wavelength of the light beam. Therefore, when the optical distance from the first interface 116 is no greater than the wavelength of the light beam to be converted, the absorption unit 114 can selectively absorb the component that could be incident on the opposite photo diode.

Next, a case in which the absorption units 114 are farther from the substrate 120 than the second interface 117 will be described.

As can be seen from FIGS. 4A and 4B, the light beams 11 and 12 incident on the pixel 101 at small angles of incidence are condensed near the center of the incident end 113 but spread toward the peripheral sides of the pixel 101 at a position higher above the second interface 117.

Therefore, as (the absolute value of) the optical distance between the absorption units 114 and the incident end 113 in the third direction is larger, a light beam incident on the pixel 101 at a small angle of incidence is also absorbed by the absorption units 114. Accordingly, it is preferable that (the absolute value of) the optical distance between the absorption units 114 and the incident end 113 in the third direction be smaller.

As described thus far, it is preferable that (the absolute value of) the optical distance between the absorption units 114 and the incident end 113 in the third direction be smaller. In particular, a case in which the positions of the absorption units 114 in the third direction coincides\ with the position of the incident end 113 in the third direction (a case in which the optical distance between the absorption units 114 and the incident end 113 in the third direction is zero) is most preferable.

It is to be noted that, when (the surfaces of) the absorption units 114 (on the side from which a light beam is emitted) are farther from the substrate 120 than the incident end 113 in the third direction, the disposition of the absorption units can be determined independently from the process of manufacturing the waveguide unit. As a result, the flexibility in the disposition of the absorption units improves, and it becomes easier to manufacture the absorption units. Thus, the aforementioned configuration is preferable.

It is more preferable that an inner lens 104 can be provided between the incident end 113 and the microlens 102 (on the side of the core 111 toward the microlens 102), as illustrated in FIG. 7A. This is because the inner lens 104 can condense a light beam incident on the pixel 101 at a large angle of incidence relative to the third direction at the center of the pixel 101 above the incident end 113.

Although FIG. 2 illustrates a case in which the absorption unit 114 does not cross the interface (first interface) 116 of the cladding 112 on the side in the first direction, the absorption unit 114 may partially extend onto the core 111 (the absorption unit 114 may cross the first interface 116), as illustrated in FIG. 7B.

As the absorption units 114 are closer to the center of the incident end 113 as viewed in the third direction, the quantity of the absorbed light increases. As a result, the AF accuracy or the ranging accuracy in a case in which the F-number is small can be improved. As the absorption units 114 are closer to the center of the incident end 113 as viewed in the third direction, not only the light beam that has coupled to a higher-order waveguide mode but also the light beam that has coupled to a lower-order waveguide mode is more easily absorbed. As a result, the AF accuracy or the ranging accuracy in a case in which the F-number is large decreases.

Accordingly, when the AF accuracy or the ranging accuracy only in the case in which the F-number is small is to be given importance, such as the case in which an imaging optical system having a fixed stop is used, it is preferable that the absorption units be disposed closer to the center of the incident end 113 as viewed in the third direction. On the other hand, when the AF accuracy or the ranging accuracy not only in the case in which the F-number is small but also in the case in which the F-number is large is to be given importance, such as the case in which an imaging optical system having a variable stop is used, it is preferable that the absorption units be disposed farther from the center of the incident end 113 as viewed in the third direction. The positions of the absorption units 114 as viewed in the third direction may be determined on the basis of the range of the F-number through which the AF accuracy or the ranging accuracy is to be given importance.

The shape of the absorption unit 114 may be rectangular as viewed in the third direction, as illustrated in FIG. 7C, or may be a different polygonal shape, a circle, or the like. In addition, as illustrated in FIG. 7D, the absorption unit 114 may be shared by a plurality of pixels (two pixels in this case) adjacent in the first direction (+X-axis direction). In FIGS. 7C and 7D, the dashed lines indicate the incident end 113.

Although FIG. 2 illustrates a case in which the absorption units 114 are disposed in the first direction, on two sides of the core, with the core interposed therebetween, the absorption unit 114 may be provided only on one side of the core. In this case, the component that is incident on an unintended photo diode decreases only of a light beam incident obliquely in the +X-axis direction or the −X-axis direction. Meanwhile, when the absorption units 114 are provided on the two sides of the core, with the core interposed therebetween, as illustrated in FIG. 2, the component that is incident on an unintended photo diode decreases for both of a light beam incident obliquely in the +X-axis direction and a light beam incident obliquely in the −X-axis direction. Accordingly, it is preferable that the absorption units be provided on the two sides of the core, with the core interposed therebetween, as illustrated in FIG. 2.

As the inner diameter of the interface of the cladding 112 on the side toward the microlens 102 (the diameter of the incident end 113) is smaller by the use of the use of the absorption units 114, a light beam that has coupled to a higher-order waveguide mode is less likely to be incident on the photo diode that is not the desired photo diode, and thus the advantageous effect of the present invention is enhanced.

The preferable size of the inner diameter of the interface of the cladding 112 on the side toward the microlens 102 varies in accordance with the minimum F-number of the imaging optical system to be used and the length of the waveguide unit determined by the manufacturing conditions.

Specifically, it is preferable that the aforementioned size be no greater than twice the value obtained by multiplying the size of the cladding 112 in the third direction by the maximum angle of incidence of the light beam to be converted relative to the pixel 101 (the maximum value of the angle of incidence relative to the third direction, hereinafter, simply referred to as a maximum angle of incidence). In other words, it is preferable that the length of the incident end 113 in the first direction be no greater than the value obtained by dividing the size of the cladding 112 in the third direction by the minimum F-number of the imaging optical system to be used.

In a strict sense, the propagation of a light beam in the pixel is depicted in a waveguide mode, but the description is provided hereinafter through the approximation of geometrical optics with reference to FIG. 8.

As shown in FIG. 8, the pixel 101 is designed so as to receive a light beam in an angular range determined by the F-number of the imaging optical system, and thus a light beam that has passed through the edge of the aperture of the imaging optical system is incident on the incident end 113 near an edge thereof in the first direction.

A light beam incident on the waveguide unit is reflected at the interface 116, propagates through the waveguide unit, and is emitted from the exit end 115 (see FIG. 2). The position x at which the principal ray of the light beam incident on the incident end 113 around the edge portion thereof in the first direction is emitted through the exit end 115 can be expressed as in the following expression (1).

x=h×tan θ≈h×θ (1)

In the above, h represents the length of the waveguide unit in the propagation direction, and θ represents the angle of incidence of the light beam (the maximum angle of incidence, relative to the third direction, of the light beam that the waveguide unit can propagate). In addition, x represents the distance between the edges of the incident end 113 in the first direction (the inner diameter of the cladding 112 on the side toward the microlens 102). Here, in the approximation, it is approximated that a light beam is incident on the opposite photo diode that is not the desired photo diode when the principal ray is emitted from the exit end 115 at a position on an opposite side relative to the center of the waveguide unit. Then, the advantageous effect of the present invention is enhanced when the length w of the incident end 113 in the first direction satisfies the following expression (2).

w≦2×x≈w≦2×h×θ (2)

In other words, it is preferable that the length w of the incident end 113 in the first direction be no greater than twice the value obtained by multiplying the size of the waveguide unit in the third direction (the length of the waveguide unit in the propagation direction) by the maximum angle of incidence, relative to the third direction, of the light beam that the waveguide unit can propagate. Furthermore, the length w can also be expressed as in the following expression (3) on the basis of the relationship (F=2×θ) between the F-number of the imaging optical system and the maximum angle of incidence, relative to the third direction, of the light beam that the waveguide unit can propagate.

w≦2×h×θ≈w≦h÷F (3)

In other words, it is preferable that the length w of the incident end 113 in the first direction be no greater than the value obtained by dividing the size of the waveguide unit in the third direction (the length of the waveguide unit in the propagation direction) by the minimum F-number of the imaging optical system to be used.

For example, when the size of the waveguide unit in the third direction is 2.0 μm and the minimum F-number of the imaging optical system to be used is 1.4, the advantageous effect of the present invention is enhanced in a case in which the diameter of the incident end 113 in the first direction is no greater than 1.4 The diameter of the incident end 113 in the first direction is the length of a portion of the incident end 113 that is longest in the first direction. For example, the aforementioned diameter is the diameter when the incident end 113 is circular, the major axis when the shape of the incident end 113 is an ellipse having the major axis in the first direction, or the length of a side when the shape of the incident end 113 is a square having a side along the first direction.

In addition, the advantageous effect of the present invention is enhanced as the optical distance between the substrate 120 (the pair of photo diodes 121 and 122) and the third interface 118 in the third direction is longer. The reason therefor is as follows. As the third interface 118 (the exit end 115) is farther from the substrate 120 (the pair of photo diodes 121 and 122), the distance that a light beam that has coupled to a higher-order waveguide mode propagates with a spread after being emitted from the waveguide unit increases.

Specifically, it is preferable that the optical distance between the substrate 120 (the pair of photo diodes 121 and 122) and the exit end 115 in the third direction be no less than the wavelength of the light beam to be converted.

All of the pixels included in the image sensor 100 may be the pixels 101. Alternatively, some of the pixels may be the pixels 101, and the remaining pixels may be image pickup pixels (pixel having only one photo diode). AF or ranging may be carried out with the use of a signal acquired by the pixel 101, and an image may be generated with the use of a signal acquired by the image pickup pixel. In addition, a signal for a captured image of a nearby pixel 101 may be generated with the use of a signal acquired by the image pickup pixel.

When all of the pixels included in the image sensor 100 are the pixels 101, AF or ranging of the entire region of the image sensor 100 becomes possible. In addition, a signal obtained by adding signals acquired by the photo diodes 121 and 122 included in each pixel can be used as a signal for a captured image.

The pupil splitting direction does not have to be the X-axis direction and may be the Y-axis direction or a diagonal direction. In addition, a plurality of pixels having different pupil splitting directions may be provided. With this configuration, high-precision AF or high-precision ranging can be carried out irrespective of the direction in which the contrast of an object changes.

In the first exemplary embodiment, an example in which the present invention is applied to a so-called front surface incident type image sensor in which the wires 123 are provided on the side on which the light beams are incident on the first photo diode 121 and the second photo diode 122 has been illustrated. Alternatively, the present invention may be applied to a so-called back surface incident type image sensor in which the wires 123 are provided on the side opposite to the side on which the light beams are incident on the pair of photo diodes 121 and 122.

In the front surface incident type image sensor, when the wires 123 are provided closer to the microlens than the absorption units 114, the light beams are absorbed by the wires 123, and the electrical characteristics of the wires 123 become unstable. In addition, the aforementioned configuration renders it necessary to dispose an absorption unit between the plurality of wires 123 and 123 or underneath the wire 123, and thus the flexibility in the wire layout is restricted.

Accordingly, as illustrated in FIG. 2, it is preferable that the absorption units 114 be provided closer to the microlens than the wires 123 in the front surface type image sensor. When a plurality of wires 123 are to be provided, it is preferable that the absorption units 114 be provided closer to the microlens than the wire 123 that is provided closest to the microlens.

### Second Exemplary Embodiment

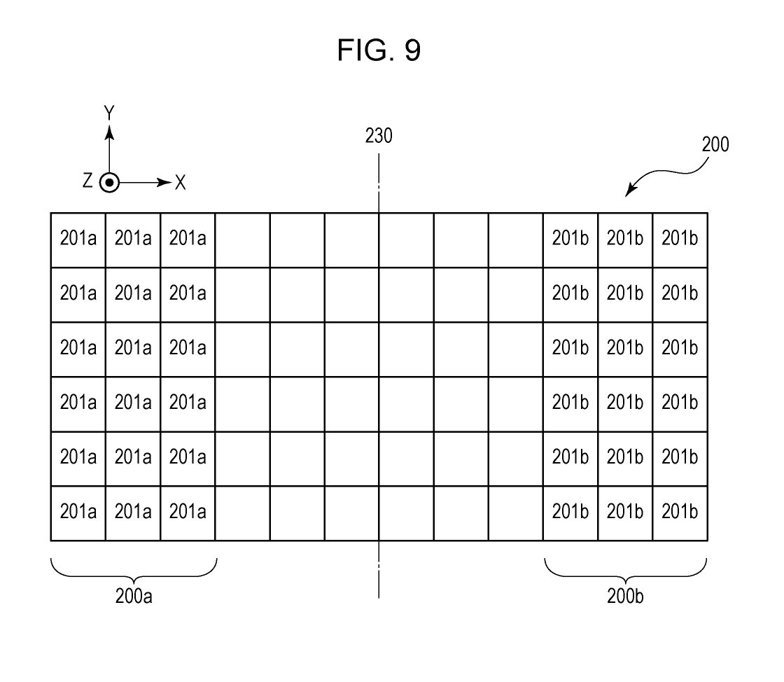

In an image sensor 200 according to a second exemplary embodiment, the shape of an absorption unit 214 differs depending on the position of a pixel 201 in the image sensor 200. FIG. 9 illustrates the arrangement of the pixels in the image sensor 200 according to the second exemplary embodiment. Pixels 201a are provided in a peripheral region 200a of the image sensor 200 in the first direction (−X-axis direction), and pixels 201b are provided in a peripheral region 200b in the first direction (+X-axis direction).

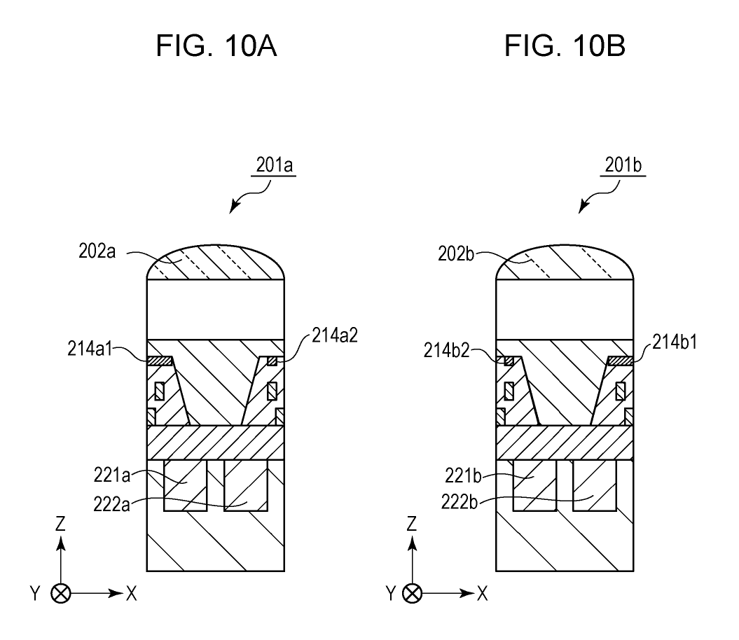

FIGS. 10A and 10B are sectional views illustrating configurations of the pixels 201a and 201b, respectively. The pixels 201a and 201b differ from the pixel 101 illustrated in FIG. 2 in terms of the size of the absorption unit.

Specifically, in the pixel 201a provided in the peripheral region 200a (−X-axis direction) of the image sensor, the volume of a first absorption unit 214a1 serving as the absorption unit provided in the −X-axis direction is larger than the volume of a second absorption unit 214a2 serving as the absorption unit provided in the +X-axis direction. In addition, in the pixel 201b provided in the peripheral region 200b (+X-axis direction) of the image sensor, the volume of a first absorption unit 214b1 provided in the +X-axis direction is larger than the volume of a second absorption unit 214b2 provided in the −X-axis direction.

In other words, in the peripheral regions of the image sensor, the volumes of the first absorption units 214a1 and 214b1 each having a larger distance in the first direction to the center line that passes through the center of the image sensor 200 and that is parallel to the second direction are larger than the volumes of the second absorption units 214a2 and 214b2. With this configuration, high-precision AF or high-precision ranging can be carried out irrespective of the position of the pixel in the image sensor. This will be described hereinafter.

The angle of incidence of a principal ray incident on a pixel differs depending on the position of the pixel in the image sensor 200. Specifically, the principal ray is incident obliquely in the −X-axis direction and the −Z-axis direction in the peripheral region 200a in the −X-axis direction, and the principal ray is incident obliquely in the +X-axis direction and the −Z-axis direction in the peripheral region 200b in the +X-axis direction.

The pixels 201a are provided in the peripheral region of the image sensor in the −X-axis direction, and thus the maximum angle of incidence of a light beam incident obliquely in the −X-axis direction and the −Z-axis direction is larger than the maximum angle of incidence of a light beam incident obliquely in the +X-axis direction and the −Z-axis direction in the pixels 201a. Therefore, a light beam incident obliquely in the −X-axis direction and the −Z-axis direction is condensed by a microlens 202a at a position closer to the edge portion of the incident end 113 in the first direction (−X-axis direction).

As described above, a light beam condensed closer to the edge portion of the incident end 113 in the first direction couples to a higher-order waveguide mode and is incident on both photo diodes 221a and 222a, causing the pupil splitting performance to deteriorate.

Therefore, by increasing the volume of the absorption unit 214a1 in the −X-axis direction in which a light beam incident obliquely in the −X-axis direction and the −Z-axis direction is condensed, the pupil splitting performance can be further improved.

On the other hand, the pixels 201b are provided in the peripheral region of the image sensor in the +X-axis direction, and thus the maximum angle of incidence of a light beam incident obliquely in the +X-axis direction and the −Z-axis direction is larger than the maximum angle of incidence of a light beam incident obliquely in the −X-axis direction and the −Z-axis direction in the pixels 201b. Therefore, a light beam incident obliquely in the +X-axis direction and the −Z-axis direction is condensed by a microlens 202b at a position closer to the edge portion of the incident end 113 in the first direction (+X-axis direction). As described above, a light beam condensed closer to the edge portion of the incident end 113 in the first direction couples to a higher-order waveguide mode and is incident on both photo diodes 221b and 222b, causing the pupil splitting performance to deteriorate.

Therefore, by increasing the volume of the absorption unit 214b1 in the +X-axis direction in which a light beam incident obliquely in the +X-axis direction and the −Z-axis direction is condensed, the pupil splitting performance can be further improved.

FIGS. 10A and 10B illustrate a case in which the length of the absorption unit (the size of the absorption unit in the first direction) is varied as a method of varying the volume of the absorption unit. Alternatively, the height of the absorption unit (the size of the absorption unit in the third direction) may be varied, or the length in the first direction and the thickness of the absorption unit may both be varied.

However, as illustrated in FIGS. 10A and 10B, varying only the length of the absorption unit in the first direction without varying the height of the absorption unit is preferable since this configuration makes the manufacturing easier.

With respect to the center region of the image sensor. The inclination of the angle of incidence of a principal ray incident on a pixel is small, and thus it is preferable that the volumes of the absorption units provided on the two sides of the image sensor in the first direction be equal to each other.

It is preferable that the peripheral regions be each a region of which the distance from a straight line 230 that passes through the center of the image sensor and that extends in a direction perpendicular to the first direction is no less than 0.40 times the length of the image sensor in the first direction, and it is more preferable that the stated distance be no less than 0.25 times the length of the image sensor in the first direction.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-178951 filed Sep. 10, 2015, which is hereby incorporated by reference herein in its entirety.

What is claimed is:

1. An image sensor, comprising:
a plurality of pixels arrayed in a two-dimensional plane containing a first direction and a second direction perpendicular to the first direction,
wherein each of the plurality of pixels includes, arranged in a third direction perpendicular to the plane,
a microlens,
a waveguide unit having a core and a cladding, the waveguide unit being capable of propagating light transmitted through the microlens, and
a pair of photo diodes arrayed in the first direction, the pair of photo diodes being configured to carry out photoelectric conversion of light guided by the waveguide unit,
wherein each of the pixels includes an absorption unit that is electrically independent, the absorption unit having an optical absorptance with respect to a light beam to be photoelectrically converted by the pair of photo diodes higher than an optical absorptance of the core and of the cladding,
wherein the absorption unit is provided in the first direction of the core as viewed in the third direction, and
wherein an optical distance between the absorption unit and an interface of the cladding on the side toward the microlens in the third direction is no greater than a wavelength of the light beam.

2. The image sensor according to claim 1,
wherein an optical distance between the absorption unit and an interface of the cladding and the core on the side in the first direction is no greater than the wavelength of the light beam to be converted.

3. The image sensor according to claim 1,
wherein the absorption unit crosses an interface of the cladding and the core on the side in the first direction.

4. The image sensor according to claim 1,
wherein a wire is provided, and
wherein the absorption unit is closer to the microlens than the wire.

5. The image sensor according to claim 1,
wherein an inner lens on which the light transmitted through the microlens is incident is provided, and
wherein the inner lens is closer to the microlens than the core.

6. The image sensor according to claim 1,
wherein an inner diameter of an interface of the cladding and the core on the side toward the microlens is no greater than twice a value obtained by multiplying a size of the cladding in the third direction by a maximum angle of incidence of the light beam to be converted relative to the plane.

7. The image sensor according to claim 1,
wherein an inner diameter of an interface of the cladding and the core on the side toward the microlens is no greater than 1.4 μm.

8. The image sensor according to claim 1,
wherein an optical distance between the pair of photo diodes and an interface of the cladding and the core on the side toward the pair of photo diodes in the third direction is no less than the wavelength of the light beam to be converted.

9. The image sensor according to claim 1,
wherein the absorption unit is provided on two sides of the core with the core interposed therebetween in the first direction.

10. The image sensor according to claim 9,
wherein the absorption unit includes a first absorption unit having a larger distance in the first direction to a center line that passes through a center of the image sensor and that is parallel to the second direction and a second absorption unit, and
wherein a size of the first absorption unit in the first direction is larger than a size of the second absorption unit in the first direction.

11. The image sensor according to claim 9,
wherein the absorption unit includes a first absorption unit having a larger distance in the first direction to a center line that passes through a center of the image sensor and that is parallel to the second direction and a second absorption unit, and
wherein a size of the first absorption unit in the third direction is larger than a size of the second absorption unit in the third direction.

12. The image sensor according to claim 9,
wherein the absorption unit includes a first absorption unit having a larger distance in the first direction to a center line that passes through a center of the image sensor and that is parallel to the second direction and a second absorption unit, and
wherein a volume of the first absorption unit is larger than a volume of the second absorption unit.

13. The image sensor according to claim 9,
wherein the plurality of pixels are arrayed in the first direction, and
wherein the absorption unit is shared by a plurality of pixels adjacent to each other in the first direction.

14. An image sensor, comprising:
a plurality of pixels arrayed in a two-dimensional plane containing a first direction and a second direction perpendicular to the first direction,
wherein each of the plurality of pixels includes, in a third direction perpendicular to the plane,
a microlens,
a waveguide unit having a core and a cladding, the waveguide unit being capable of propagating light transmitted through the microlens, and
a pair of photo diodes arrayed in the first direction, the pair of photo diodes being configured to carry out photoelectric conversion of light guided by the waveguide unit,
wherein each of the pixels includes an absorption unit that is electrically independent, the absorption unit having an optical absorptance with respect to a light beam to be photoelectrically converted by the pair of photo diodes higher than an optical absorptance of the core and of the cladding,
wherein the absorption unit is provided in the first direction of the core as viewed in the third direction, and
wherein the absorption unit is provided closer to the microlens than an interface of the cladding on the side toward the microlens.

15. An image pickup apparatus, comprising:
an imaging optical system; and
the image sensor according to claim 1, the image sensor being configured to receive light from the imaging optical system.

16. An image pickup apparatus, comprising:
an imaging optical system; and
the image sensor according to claim 14, the image sensor being configured to receive light from the imaging optical system.

17. The image pickup apparatus according to claim 15,
wherein an inner diameter of an interface of the cladding on the side toward the microlens is no greater than a value obtained by dividing a size of the cladding in the third direction by a minimum F-number of the imaging optical system.
